(19) United States
(12) Patent Application Publication
(10) Pub. No.: US 2012/0326577 A1
(43) Pub. Date: Dec. 27, 2012

(54) Waterproof covering member for a panel of an electronic device

(76) Inventor: Heng-Sheng Lin, New Taipei City (TW)

(21) Appl. No.: 13/164,782

(22) Filed: Jun. 21, 2011

(51) Int. Cl. H05K 5/02

(52) U.S. Cl. 312/223.1

(57) ABSTRACT

A plastic waterproof covering arrangement includes a peripheral edge of arcuate section; a first set of a plurality of concentric structures; a second set of a plurality of concentric structures; and a brace member for separating the first set of concentric structures from the second set of concentric structures; wherein each of the concentric structures comprises a plurality of concentric circular grooves; and wherein at least one of the concentric structures is provided with a transverse diametrical slit and a circular hole through the slit and a center of the concentric structure.

### BACKGROUND OF THE INVENTION

1. Field of the Invention The invention relates to waterproof arrangements and more particularly to a waterproof covering member for a panel mounted on an electronic device (e.g., computer housing).

2. Description of Related Art

Devices or components having a waterproof or water-resistant arrangement are well known in the art. For example, there are waterproof connectors, plugs, cables, lights, etc. commercially available.

Notwithstanding the prior art, the invention is neither taught nor rendered obvious thereby.

### SUMMARY OF THE INVENTION

It is therefore one object of the invention to provide a plastic waterproof covering arrangement comprising a peripheral edge of arcuate section; a first set of a plurality of concentric structures; a second set of a plurality of concentric structures; and a brace member for separating the first set of concentric structures from the second set of concentric structures; wherein each of the concentric structures comprises a plurality of concentric circular grooves; and wherein at least one of the concentric structures is provided with a transverse diametrical slit and a circular hole through the slit and a center of the concentric structure.

The above and other objects, features and advantages of the invention will become apparent from the following detailed description taken with the accompanying drawings.

### BRIEF DESCRIPTION OF THE DRAWINGS

FIG. 1 is a perspective view of a waterproof covering member for a panel of an electronic device according to the invention;

FIG. 2 is another perspective view of the waterproof covering member viewed from the back;

FIG. 3 is a fragmentary view of the right side of FIG. 2 with a portion being enlarged for showing details;

FIG. 4 is an enlarged view of FIG. 3;

FIG. 5 is a view similar to FIG. 4 with a slit being formed by cutting;

FIG. 6 is a view similar to FIG. 4 with a circular hole being formed by cutting;

FIG. 7 is a view similar to FIG. 6 showing a cable passing through the hole;

FIG. 8 is a perspective view of an electronic device with a cable passing through the waterproof covering member mounted on a panel of the electronic device; and

FIG. 9 is an exploded perspective view showing the waterproof covering member removed from the panel of the electronic device.

### DETAILED DESCRIPTION OF THE INVENTION

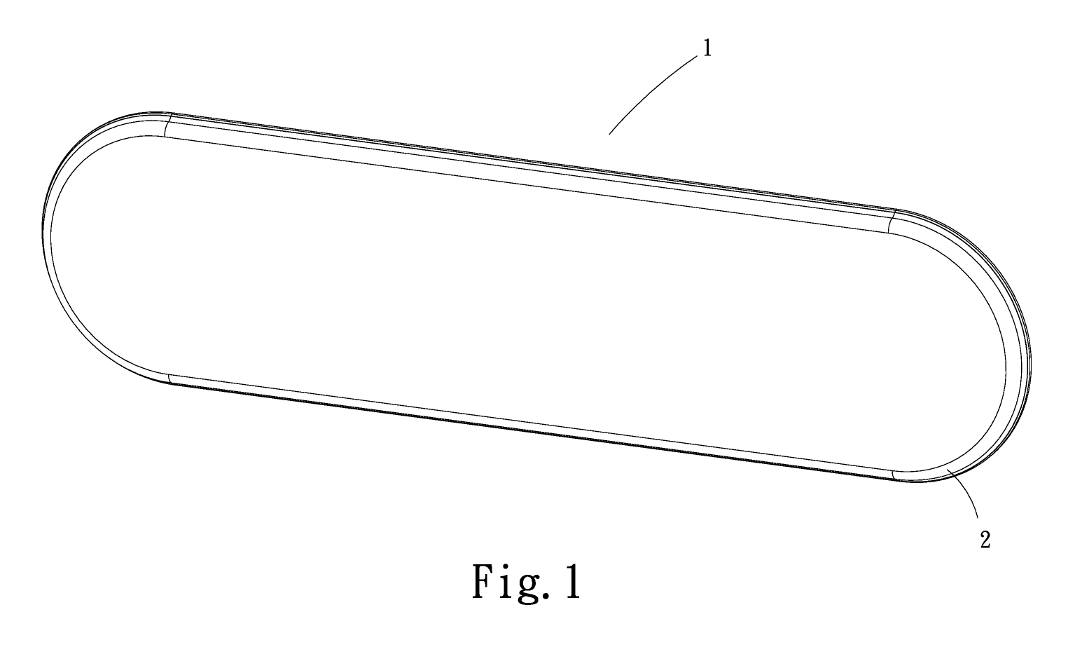

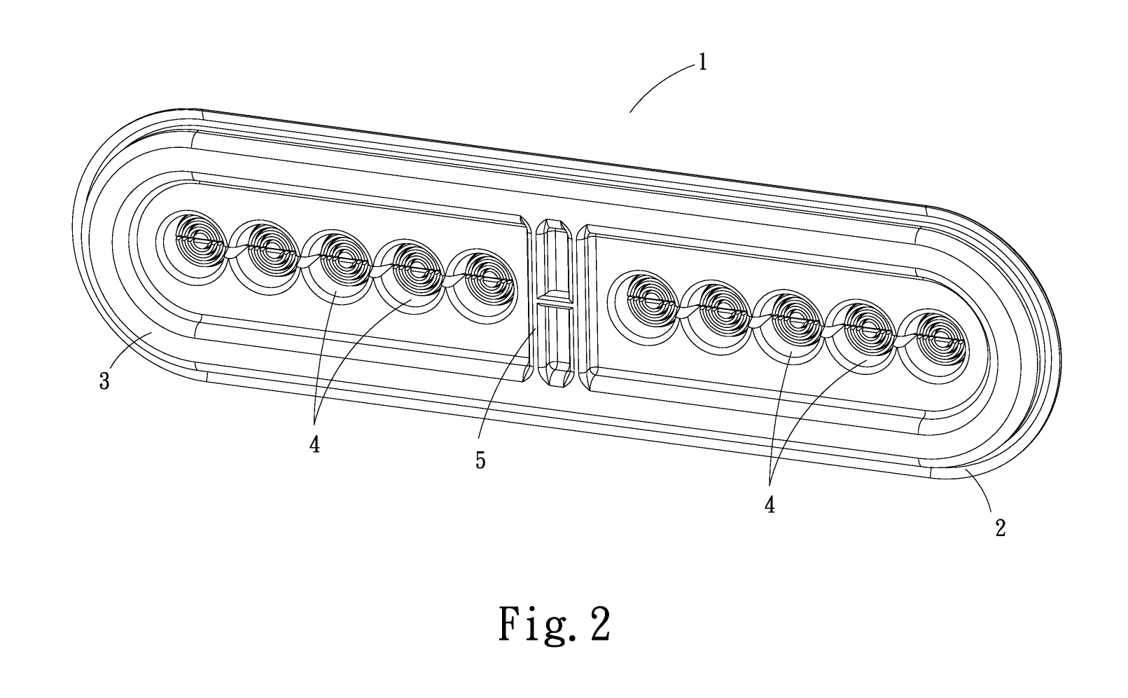

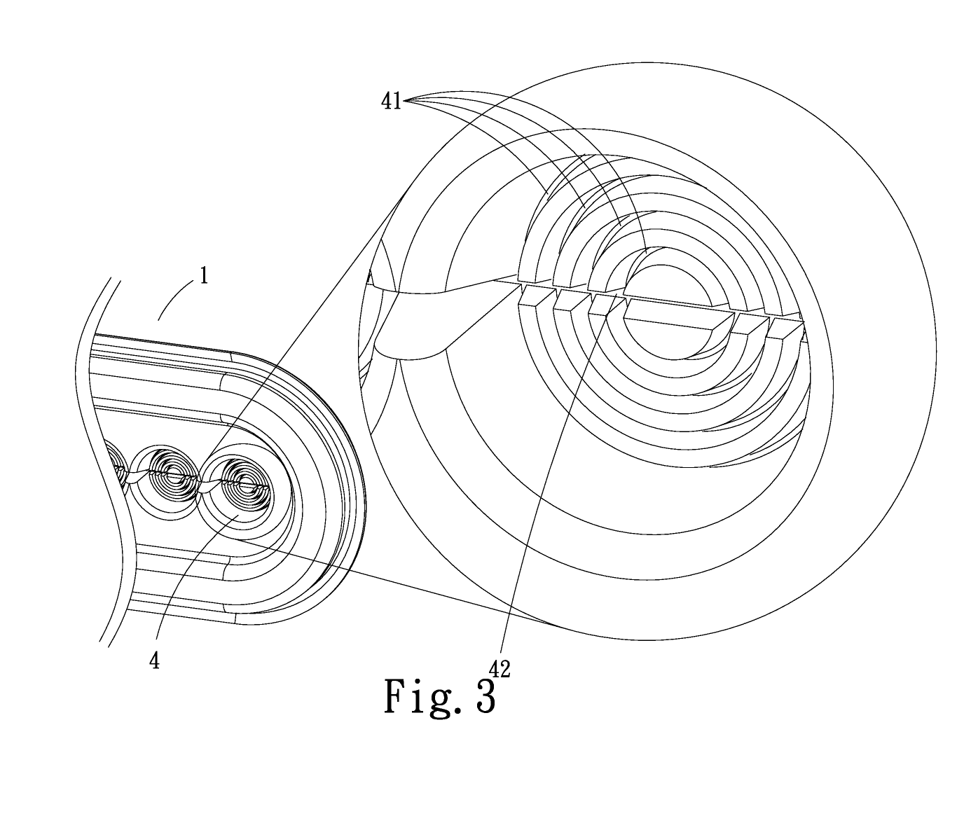

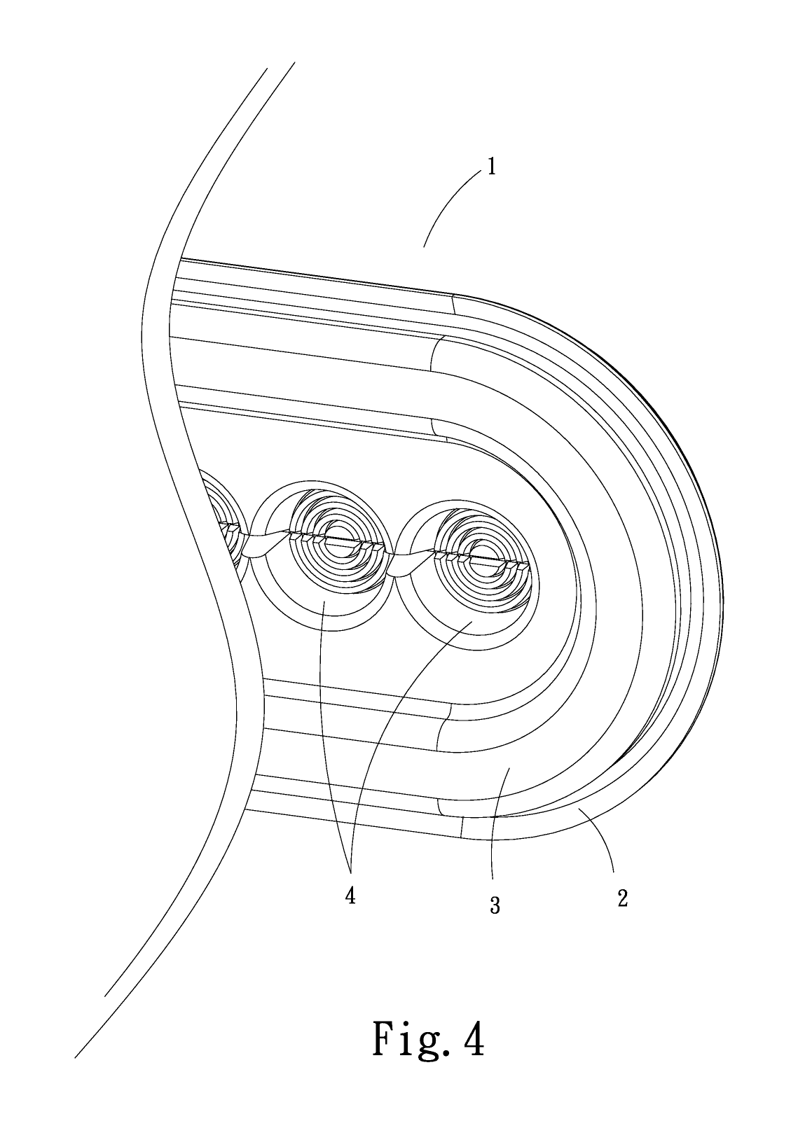

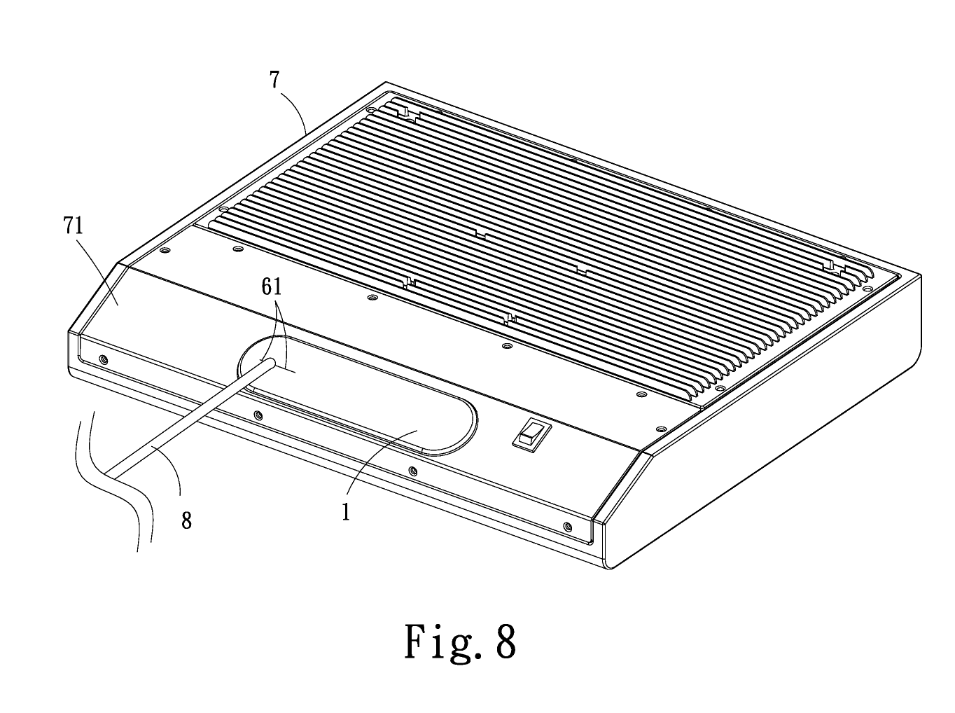

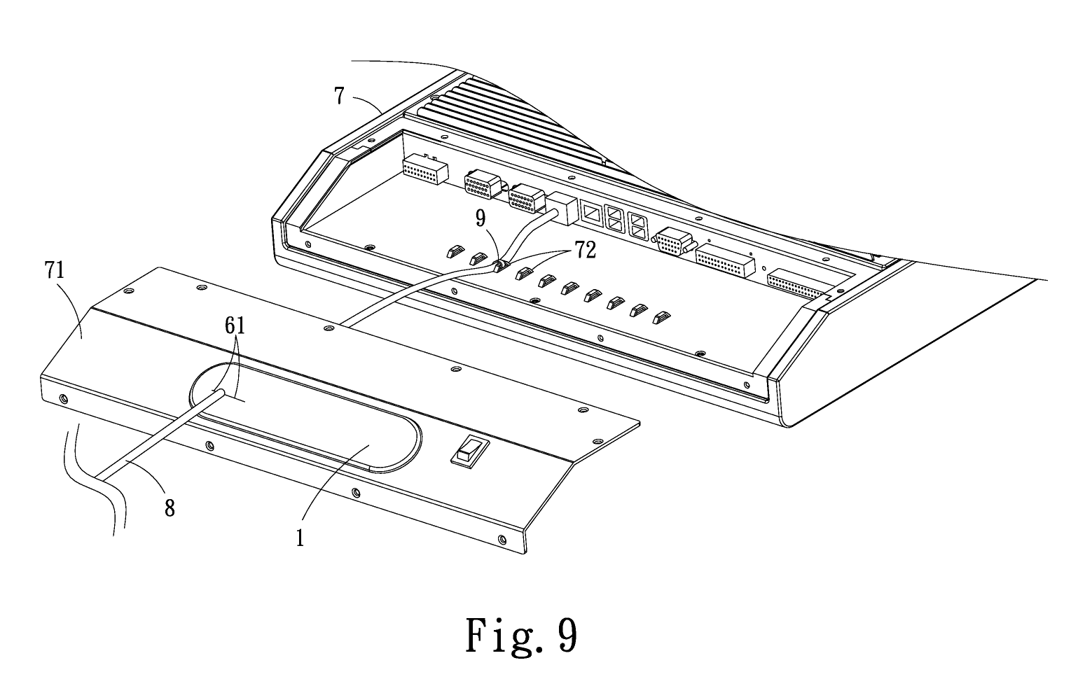

Referring to FIGS. 1 to 9, a waterproof covering member 1 mounted on a panel 71 of an electronic device (e.g., computer housing) 7 in accordance with the invention comprises the following components as discussed in detail below.

The waterproof covering member 1 is an integral member and formed of silicon rubber or rubber. The waterproof covering member 1 is oval and has a smooth front surface. The waterproof covering member 1 comprises a peripheral edge 2 of arcuate section. On the back of the waterproof covering member 1 there are provided a left set of connected a plurality of concentric structures 4, a right set of connected a plurality of concentric structures 4, and an H-shaped brace member 5 in the middle for separating the left set of concentric structures 4 from the right set of concentric structures 4. On the back of the waterproof covering member 1 there is further provided a closed loop 3 interconnecting the peripheral edge 2 and a section including the left set of connected concentric structures 4, the right set of connected concentric structures 4, and the brace member 5. Both the peripheral edge 2 and the closed loop 3 are sealingly engaged with the mouth of an opening (not numbered) on a panel 71 of an electronic device (e.g., computer housing) 7 due to complimentary shape when the waterproof covering member 1 is mounted on the panel 71 by snapping.

A cable 8 can pass through one of the concentric structures 4 to connect to one of ports of the computer housing 7. For fastening purpose, a series of tabs 72 are provided in the computer housing 7. The cable 8 may be fixed at the tab 72 by tying the cable 8 to the tab 72 with a plastic cable tie 9. The concentric structure 4 comprises a plurality of concentric circular grooves 41 and a transverse diametrical trough 42 through the grooves 41.

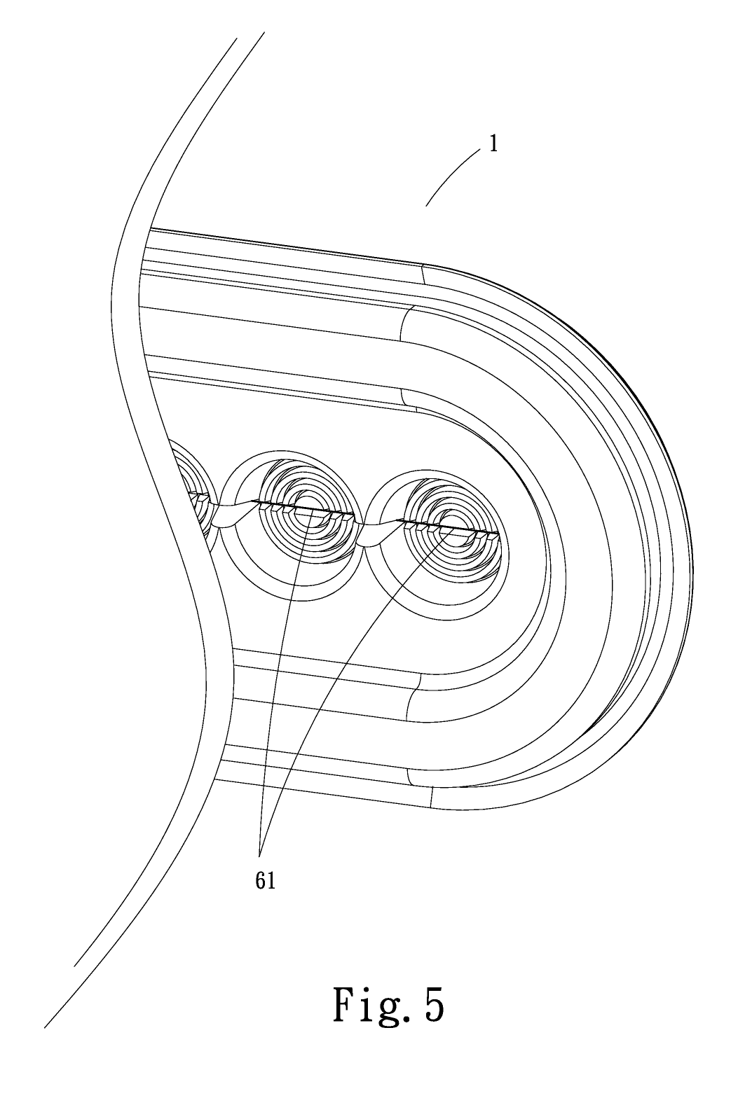

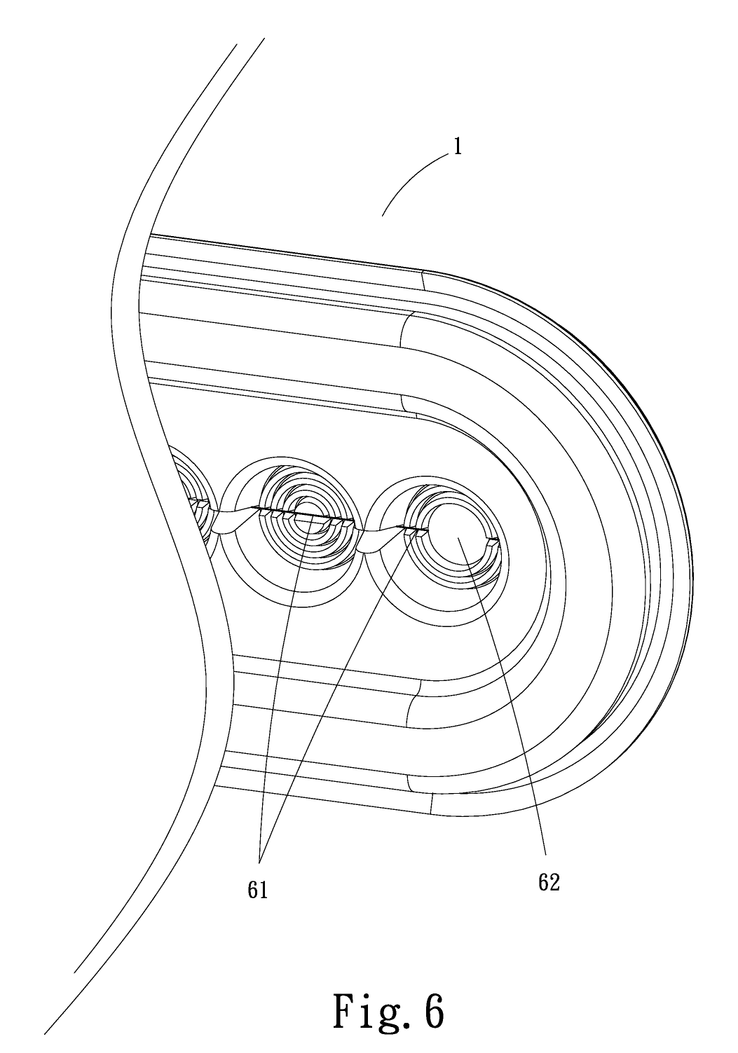

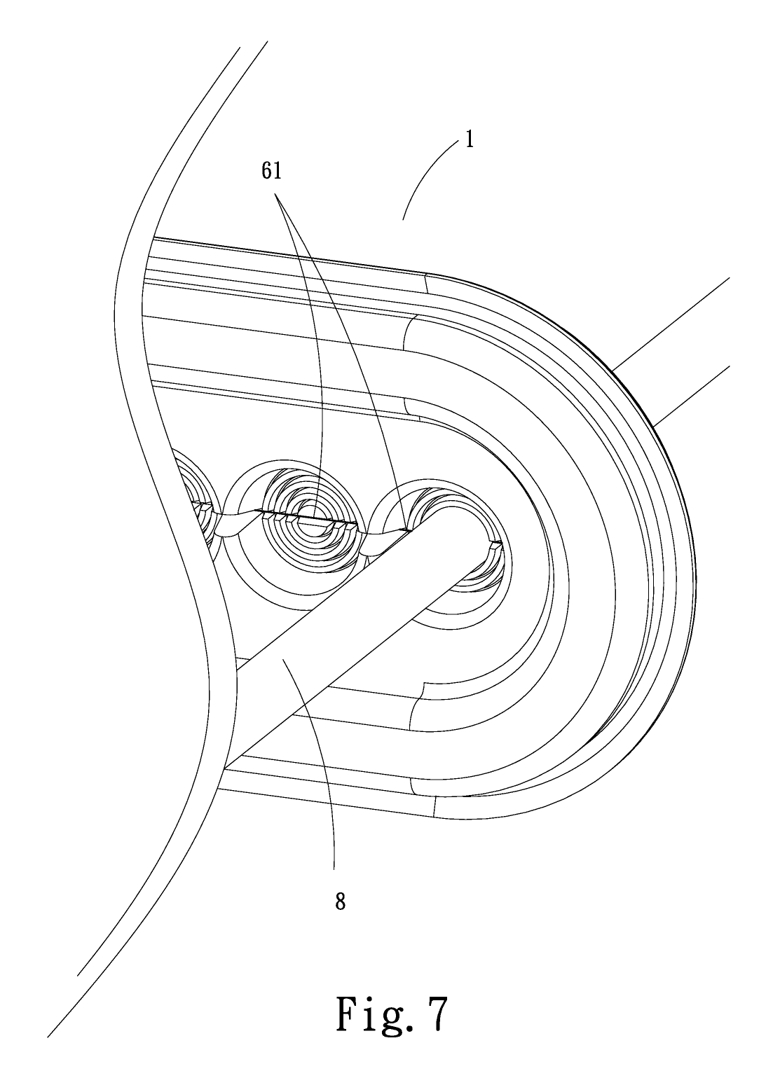

Following is a description of passing the cable 8 through the concentric structure 4. First, an individual may use a knife to cut a transverse diametrical slit 61 through the trough 42 (see FIG. 5). Next, the individual may cut a circular hole 62 through a central portion of the concentric structure 4 (see FIG. 6). The diameter of the hole 62 may be slightly less than that of the cable 8. Thus, the elasticity of the concentric structure 4 may sealingly engage the circular edge of the hole 62 with the cable 8 when the cable 8 passes through the hole 61 (see FIG. 7). Also, the slit 61 is sealingly closed also due to the elasticity of the concentric structure 4.

It is envisaged by the invention that the opening of the panel 71 is made waterproof by mounting the waterproof covering member 1 thereon.

While the invention has been described in terms of preferred embodiments, those skilled in the art will recognize that the invention can be practiced with modifications within the spirit and scope of the appended claims.

What is claimed is:

1. A plastic waterproof covering arrangement comprising:
a peripheral edge of arcuate section;
a first set of a plurality of concentric structures;
a second set of a plurality of concentric structures; and
a brace member for separating the first set of concentric structures from the second set of concentric structures;
wherein each of the concentric structures comprises a plurality of concentric circular grooves; and
wherein at least one of the concentric structures is provided with a transverse diametrical slit and a circular hole through the slit and a center of the concentric structure.
